(19) United States
(12) Patent Application Publication
(10) Pub. No.: US 2026/0334247 A1
(43) Pub. Date: Oct. 22, 2026

(54) POWER MODULE PACKAGE HAVING POWER TAB

(71) Applicant: SEMICONDUCTOR COMPONENTS INDUSTRIES, LLC, Scottsdale, AZ (US)

(72) Inventors: Hangil SHIN, Incheon (KR); Jihwan KIM, Seoul (KR); Taekyun KIM, Bucheon (KR); Jonghwan BAEK, Seoul (KR)

(73) Assignee: SEMICONDUCTOR COMPONENTS INDUSTRIES, LLC, Scottsdale, AZ (US)

(21) Appl. No.: 19/184,839

(22) Filed: Apr. 21, 2025

(51) Int. Cl. H01L 23/495; H01L 21/56; H01L 23/31; H01L 25/07

(52) U.S. Cl. CPC H10W 70/424; H10W 70/438; H10W 74/01; H10W 74/111; H10W 90/811; H10W 90/00

(57) ABSTRACT

Implementations described herein are related to a power module package that can include, for example, a semiconductor chip assembly and a leadframe connected to the semiconductor chip assembly where the leadframe includes at least one power tab through which current associated with the semiconductor chip assembly flows. The power module package can include a molding compound partially disposed over the semiconductor chip assembly and the leadframe where the at least one power tab is exposed outside of a surface of the molding compound.

### TECHNICAL FIELD

This description relates to devices and methods for reducing stress and increasing adhesion to a molding compound for power tabs in power module packages.

### BACKGROUND

A power module package is a physical housing that contains power semiconductor devices within a single package for applications such as electric vehicles. A power module package connects to such applications using signal pins and power pins, or tabs.

### SUMMARY

In some aspects, the techniques described herein relate to a power module package, including: a semiconductor chip assembly; a leadframe connected to the semiconductor chip assembly, the leadframe including at least one power tab through which current associated with the semiconductor chip assembly flows; and a molding compound partially disposed over the semiconductor chip assembly and the leadframe, the at least one power tab being exposed outside of a surface of the molding compound.

In some aspects, the techniques described herein relate to a power module package, including: a semiconductor chip assembly; a leadframe connected to the semiconductor chip assembly, the leadframe including at least one power tab through which current associated with the semiconductor chip assembly flows; and a molding compound partially disposed over the semiconductor chip assembly and the leadframe, the at least one power tab being recessed within the molding compound.

In some aspects, the techniques described herein relate to a method, including: coupling a semiconductor die to a substrate to form a semiconductor chip assembly; coupling a leadframe to the semiconductor chip assembly, the leadframe including a frame portion and at least one power tab; at least partially encapsulating the semiconductor chip assembly and the leadframe using a molding compound such that the at least one power tab is at least partially exposed; and cutting the frame portion of the leadframe.

The details of at least one implementations are set forth in the accompanying drawings and the description below. Other features will be apparent from the description and drawings, and from the claims.

### BRIEF DESCRIPTION OF THE DRAWINGS

FIG. 1A is a diagram illustrating a top view of an example power module package according to the disclosed implementations.

FIG. 1B is a diagram illustrating a close-up view of a power tab of the example power module package.

FIG. 2A is a diagram illustrating an example leadframe assembly according to the disclosed implementations.

FIG. 2B is a diagram illustrating an example power tab of a leadframe during a trim/form process.

FIG. 2C is a diagram illustrating an example power tab after a trim/form process.

FIG. 2D is a diagram illustrating an example power tab after a trim/form process.

FIGS. 3A through 3F are diagrams illustrating cross-sectional views of example power module packages according to the disclosed implementations.

FIG. 4 is a flow chart illustrating an example method of assembling a power module package according to the disclosed implementations.

### DETAILED DESCRIPTION

This disclosure is directed to a power module package that can address several challenges related to durability of the package during use with applications. For example, implementations described in this disclosure can address issues related to adhesion of power pins or tabs to the molding compound (e.g., epoxy molding compound (EMC)) in which a semiconductor chip assembly is disposed. For example, the implementations described in this disclosure can address issues related to cracking of the power pin or tab due to mechanical stress during a trim process (e.g., trim/form process).

A power module package is a physical housing that includes (e.g., contains) power semiconductor devices within a single package for applications. Such a power module package includes a semiconductor chip assembly which provides the electrical power to the applications. The semiconductor chip assembly may be disposed on a substrate, e.g., a patterned metal layer of the substrate. The substrate may be a direct-bonded metal (DBM) substrate. In some implementations, the substrate is a direct-bonded copper (DBC) substrate. The power module package can also include a leadframe configured to provide interconnects between the semiconductor chip assembly and the applications.

The leadframe includes a frame portion, at least one signal terminal into which a signal pin is input, and at least one power tab. A signal pin is configured to carry small amounts of electrical current used for control, feedback, and communications signals. The at least one power tab can be larger (wider) and thicker than any of the at least one signal terminals and/or can be used for high currents through which electrical power from the semiconductor chip assembly flows. The at least one power tab is attached to the frame portion of the leadframe by a tie bar. The tie bar may be at least one-half (or less) of the width of the power tab.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

The power module package may also include any type of molding compound. The molding compound may be at least partially disposed over the semiconductor chip assembly and the leadframe such that the at least one signal terminal is exposed outside of the molding compound. The molding compound may be at least partially disposed over the semiconductor chip assembly so that the at least one power tab has at least a portion that is exposed outside of the molding compound. In some implementations, the molding compound may be at least partially disposed over the semiconductor chip assembly so that the at least one power tab is recessed within the molding compound and has at least a portion that is exposed outside of the recess within the molding compound. The at least one signal terminal may be disposed on (extending outside of) a sidewall surface of the molding compound.

A conventional power module package has power tabs that are disposed outside of the sidewall surface of the molding compound. For example, the power tabs of the conventional power module package may be distributed off an edge of a surface of the molding compound, opposite the edge from which the signal pins are disposed.

In some cases, the conventional power module package involves disposing the power tabs on a surface of the molding compound, e.g., a sidewall surface. For example, the power tabs may be disposed near the corners of the surface of the molding compound, to one side of the at least one signal pin. In some implementations, the molding compound in the vicinity of the at least one power tab has a smaller thickness than the molding compound away from the power tabs. Said differently, the surface of the molding compound in the vicinity of the power tabs is recessed with respect to the surface of the molding compound away from the power tabs.

A technical problem with the conventional power module package, however, is that the power tabs may adhere poorly to the surface of the molding compound, e.g., the sidewall surface. Such poor adhesion of the power tabs to the molding compound may result in compromised performance of power delivery to applications.

Another technical problem with the conventional power module package is that the power tabs have poor durability in that the power tabs may be prone to cracking. The cracking may be a result of the stress induced on the relatively wide power tabs during a trim/form processing step during manufacture of the power module package. During the trim/form processing step, the at least one power tab is separated from the frame portion of the leadframe. The separation of the at least one power tab from the frame portion of the leadframe may involve a large amount of cutting through the tie bar due to the large width of the tie bar, and such cutting may result in large amounts of mechanical stress in the at least one power tabs. In some implementations, mechanical stress in the power tab can result from performing a bus bar interconnection during the application stage of assembly. Such mechanical stress may result in a cracking a power tab, which can result in compromised performance of the power tab in delivering electrical power to applications.

A technical solution to the technical problems involves designing the leadframe so that the at least one power tab is attached to the frame portion of the leadframe by at least one prong. The at least one prong is less than one-half of the width of a power tab and is frequently much smaller. In some implementations, a prong is between one-tenth and one-fifth of the width of a power tab. In some implementations, there are more than one prong, e.g., two. In some implementations, the at least one prong, after separating from the frame portion of the leadframe, extends beyond the surface of the molding compound. In some implementations, a prong of the at least one prong is disposed in a corner of a power tab.

Another technical solution to the technical problems involves providing a bottom surface of a power tab with a textured profile, e.g., a thickness of the power tab varies along a width and/or length of the power tab. In some implementations, the textured profile is periodic, e.g., the textured profile includes a shape that repeats across the width of the power tab. In some implementations, the textured profile is irregular. In some implementations, the textured profile includes a groove and a flat portion such that the groove extends through at least a portion of the thickness of the power tab, while the flat portion has the full thickness of the power tab. In some implementations, the groove has a round shape, e.g., a portion of a circular arc, elliptical arc, oval arc, and so forth. In some implementations, the groover has a polygonal shape, e.g., a triangular shape, a rectangular, shape, a square shape, and so forth. In some implementations, the groove extends through between one-quarter and one-half of the thickness of the power tab. In some implementations, the groove extends through the thickness of the power tab.

A technical advantage of the technical solutions is that there is less mechanical stress in a power tab due to the reduced width of the prongs relative to the tie bar. The reduced mechanical stress lowers the chance of cracking in the power tab and hence increases the chances of improved performance of the power tab relative to that in the conventional power module package. Another technical advantage of the technical solutions is that the textured profile of the bottom surface of a power tab can result in improved adhesion of the power tab to the molding compound. The improved adhesion of the power tab to the molding compound reduces the risk of failure of the power tab and increases the chances of improved performance of the power tab over that in the conventional power module package.

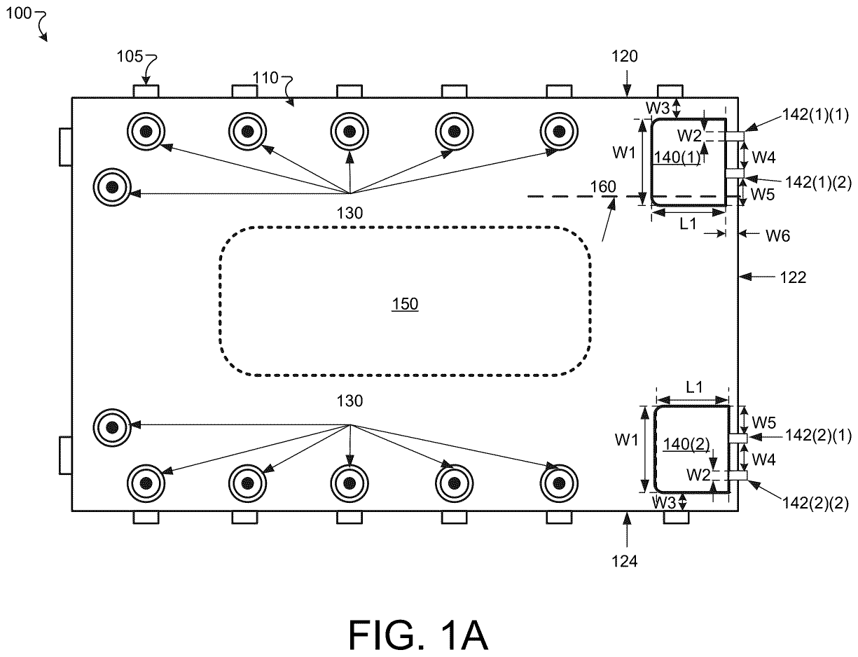

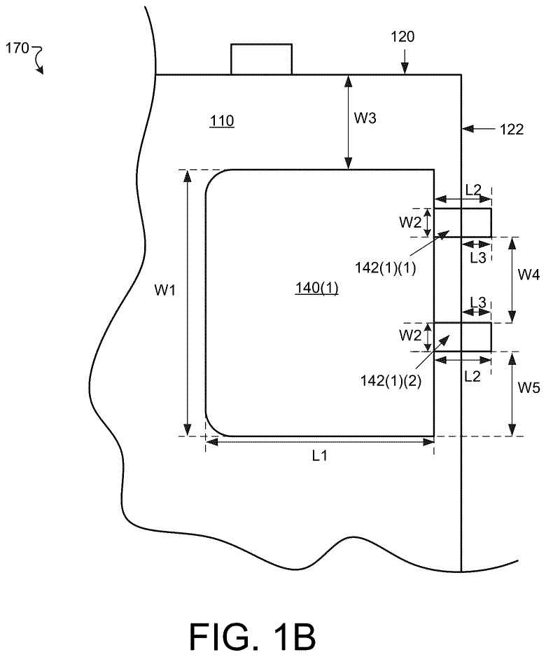

FIG. 1A is a diagram illustrating a top view of an example power module package 100. As shown in FIG. 1A, the power module package 100 includes a leadframe 105 (an exposed portion of the leadframe 105 can be seen after a trim/form process), a semiconductor chip assembly 150, signal terminals 130, power tabs 140(1) and 140(2), and a molding compound 110 that is partially disposed over the leadframe 105 and semiconductor chip assembly 150.

The leadframe 105 provides interconnects between the semiconductor chip assembly 150 and external connectors such as the signal terminals 130 and the power tabs 140(1) and 140(2). The leadframe 105 (and portions thereof) may be connected to a substrate, e.g., a DBC substrate, on which the semiconductor chip assembly 150 is disposed via solder or sinter connections. The substrate (not shown in FIG. 1A) can include patterned metal layers and an insulating layer.

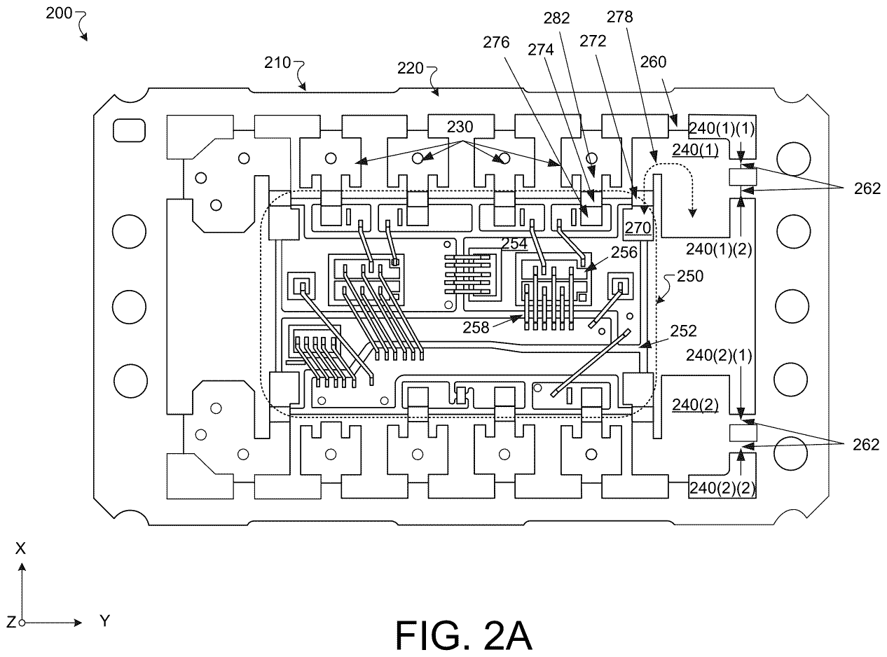

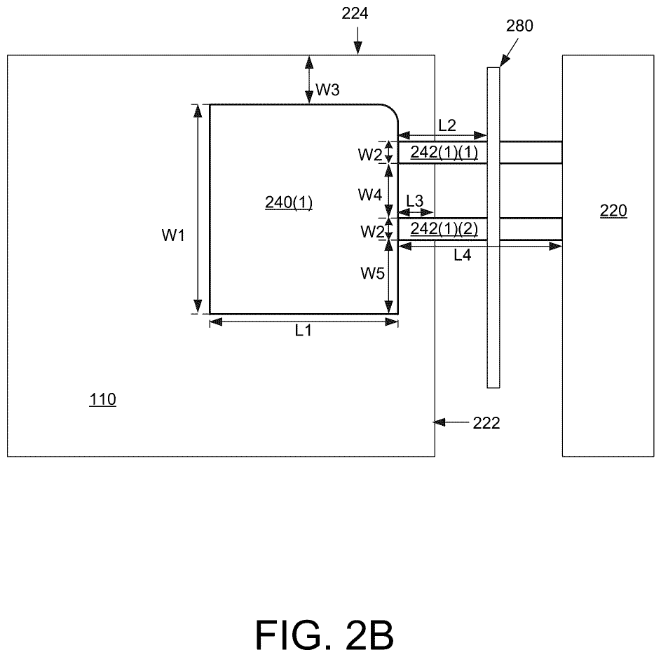

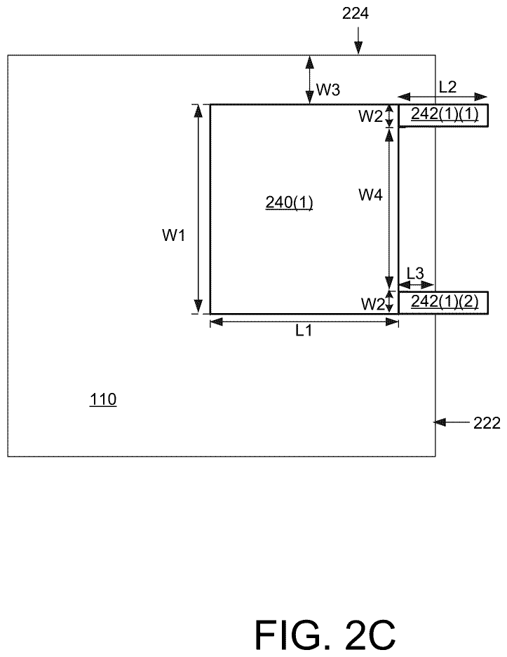

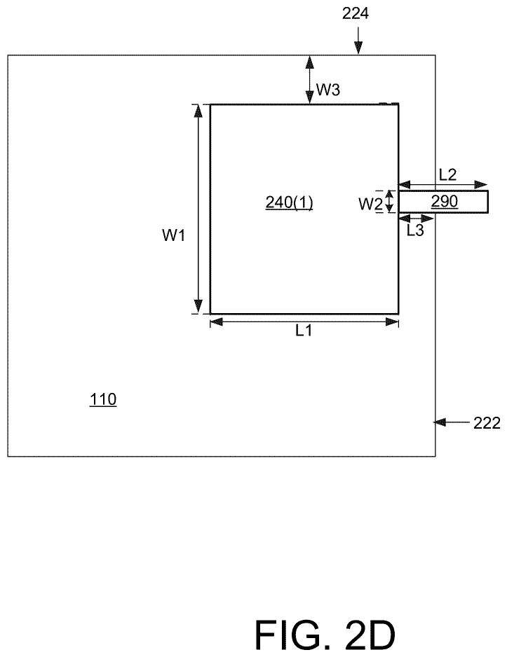

As shown in FIG. 1A, the leadframe 105 has been through the trim/form process so that there is no longer any frame portion of the leadframe 105 in the power module package 100. In some implementations, the leadframe 105 includes a conductive metal (e.g., copper) such that the power tabs 140(1) and 140(2) include a conductive metal (e.g., copper). Further details of the leadframe are shown with regard to FIGS. 2A-D. For example, additional example views of the leadframe 105 are shown as leadframe 210 in at least FIG. 2A.

The semiconductor chip assembly 150 (disposed within the molding compound 110 and represented by a dashed line) includes at least one semiconductor die that is configured to provide electrical current to the external connectors such as the signal terminals 130 and the power tabs 140(1) and 140(2) via the leadframe 105 so as to provide electrical power to an application as well as control, feedback, and communications signals sent to a printed circuit board (PCB).

The molding compound 110 is disposed over the leadframe 105 and the semiconductor chip assembly 150 such that the external connectors such as the signal terminals 130 and the power tabs 140(1) and 140(2) are left exposed. The molding compound 110 can be, for example EMC. The molding compound 110 is applied during a molding phase of the manufacture of the power module package 100. During the molding process, the molding compound 110 is recessed at the external connectors such that the recesses formed at the signal terminals 130 and the power tabs 140(1) and 140(2) have the same thicknesses relative to the thickness of the molding compound 110 away from the external connectors. Accordingly, the power tabs 140(1) and 140(2) are disposed at the same height as (e.g., within the same plane as) the bottom of the signal terminals 130.

In some implementations, the insulating layer of the substrate is exposed outside of the molding compound 110. The tie bars corresponding to the signal terminals 130 and the power tabs 140(1) and 140(2) are also exposed outside of the molding compound 110.

The signal terminals 130 are configured to allow signal pins to be inserted for providing small electrical currents to a PCB for control, feedback, and communications signals. In some implementations, the signal pins are, for example, press-fit pins. As shown in FIG. 1A, there are twelve signal terminals 130 exposed over the first portion of the molding compound 110. Any number of single terminals 130 may be included.

The power tabs 140(1) and 140(2) are disposed on a recess of the molding compound 110. The power tabs 140(1) and 140(2) are each configured to deliver relatively large currents through which electrical power from the semiconductor chip assembly 150 flows to an application. As shown in FIG. 1A, there are two power tabs 140(1) and 140(2) but this is by no means intended to be limiting; any number of power tabs may be present on the power module package 100. Nevertheless, the power tabs 140(1) and 140(2) are located near corners (in this implementation) of the surface of the molding compound 110. For example, the power tab 140(1) is located at a distance W3 from an edge 120 of a surface the molding compound 110 and a distance L2−L3 (FIG. 1B) from an edge 122 of the surface of the molding compound 110. The power tab 140(2) is located at a distance W3 from an edge 124 of the surface the molding compound 110 and a distance L2−L3 (FIG. 1B) from the edge 122 of the surface of the molding compound 110.

As shown in FIG. 1A, the power tab 140(1) and/or the power tab 140(2) are disposed within an outer perimeter of the molding compound 110. In some implementations, the power tab 140(1) and/or the power tab 140(2) are recessed within the molding compound 110. More details regarding the recessing of the power tab 140(1) and/or the power tab 140(2) are described in more detail below.

The power tabs 140(1) and 140(2) each have respective prongs, e.g., power tab 140(1) has prongs 142(1)(1) and 142(1)(2), and power tab 140(2) has prongs 142(2)(1) and 142(2)(2). The prongs 142(1)(1), 142(1)(2), 142(2)(1), 142(2)(2) replace the tie bars in conventional power module packages and result from the trim/form process of separating the frame portion of the leadframe 105. Each of the prongs 142(1)(1), 142(1)(2), 142(2)(1), 142(2) (2) is a fraction of the width of the respective power tabs 140(1) and 140(2). For example, in some implementations, each of the prongs 142(1)(1), 142(1)(2) has a width W2 that is less than one half of the width W1 of the power tab 140(1) and each of the prongs 142(2)(1), 142(2)(2) has a width W2 that is less than one half of the width W1 of the power tab 140(2). In some implementations, the width W2 of each of the prongs 142(1)(1), 142(1)(2), 142(2)(1), 142(2)(2) is between one tenth and one fifth of the width W1 of the power tabs 140(1) and 140(2). Accordingly, if the width W1 of the power tab 140(1) and 140(2) is between 5 mm and 10 mm, then the width W2 of the prongs 142(1)(1), 142(1)(2), 142(2)(1), 142(2)(2) is between 0.5 mm and 2 mm. Moreover, each of the prongs 142(1)(1), 142(1)(2), has a respective position on the power tab 140(1) and each of the prongs 142(2)(1), 142(2)(2) has a respective position on the power tab 140(2); such a position will be discussed in detail with regard to FIGS. 1B, 2C, and 2D.

The power tabs 140(1) and 140(2) each have a nominal thickness into the plane of the power module package 100. In some implementations, the thickness of the power tabs 140(1) and 140(2) is between 0.5 mm and 1.0 mm. The power tabs 140(1) and 140(2) have a top surface that is visible in a top-down view of the power module package 100 shown in FIG. 1A and a bottom surface opposite the top surface. In some implementations, the bottom surface has a textured profile, e.g., there is a variation in the thickness of the power tabs 140(1) and 140(2) in a direction, e.g., cross-section 160. In some implementations, the textured profile is periodic, e.g., the textured profile includes a shape that repeats across the width of the power tab. In some implementations, the textured profile is irregular. In some implementations, the textured profile includes a groove and a flat portion such that the groove extends through at least a portion of the thickness of the power tab, while the flat portion has the full thickness of the power tab. In some implementations, the groove has a round shape, e.g., a portion of a circular arc, elliptical arc, oval arc, and so forth. In some implementations, the groove has a polygonal shape, e.g., a triangular shape, a rectangular, shape, a square shape, and so forth. In some implementations, the groove extends through between one-quarter and one-half of the thickness of the power tab. In some implementations, the groove extends through the thickness of the power tab.

FIG. 1B is a diagram illustrating a close-up view 170 of the power tab 140(1) of the example power module package 100 (FIG. 1A). For the purposes of this disclosure, the power tab 140(2) is a mirror image of the power tab 140(1) with respect to an axis parallel to the edge 120 of the surface of the molding compound 110. In some implementations, the power tab 140(2) can have, e.g., different dimensions, prong placement, etc. than that of power tab 140(1).

As shown in FIG. 1B, the power tab 140(1) has a rectangular shape with two rounded corners away from the edge 122. In some implementations, the power tab 140(1) has a rectangular shape with only one rounded corner away from the edge 122. In some implementations, the power tab 140(1) has a rectangular shape without any rounded corners. In some implementations, the power tab 140(1) has a rectangular shape with rounded corners closer to the edge 122. In some implementations, the power tab 140(1) has a rectangular shape with a single rounded corner.

As shown in FIG. 1B, the power tab 140(1) has a width W1 of an edge parallel to edge 122 which, as discussed above, can be in some implementations between 5 mm and 10 mm. The power tab 140(1) has a length L1 of an edge parallel to edge 120 which can be in some implementations between 5 and 10 mm. The power tab 140(1) is located near the edge 120 at a distance W3 from the edge 120. The power tab 140(1) is located near the edge 122 at a distance W6 from the edge 120. The power tab 140(1) is located near the edge 120 at a distance W3 from the edge 120. In some implementations, the distance W3 and/or the distance W6 are between 1 mm and 5 mm.

As shown in FIG. 1B and discussed with regard to FIG. 1A, the power tab 140(1) has prongs 142(1)(1) and 142(1)(2). As shown in FIG. 1B, the prongs 142(1)(1) and 142(1)(2) have the same width W2; in some implementations, the prongs 142(1)(1) and 142(1)(2) have different widths. In some implementations, the width W2 of each of the prongs 142(1)(1), 142(1)(2) is less than one half of the width of W1 of the power tab 140(1). In some implementations, the width W2 of each of the prongs 142(1)(1), 142(1)(2) is between one tenth and one fifth of the width W1 of the power tab 140(1). For example, if the width W1 of the power tab 140(1) is between 5 mm and 10 mm, the width W2 of each of the prongs 142(1)(1), 142(1)(2) is between 0.5 mm and 2 mm.

The prongs 142(1)(1), 142(1)(2) are, as shown in FIG. 1B, placed not necessarily symmetrically on the edge of the power tab closest to the edge 122. For example, as shown in FIG. 1B, the prongs 142(1)(1), 142(1)(2) are spaced a distance W4 apart on the power tab 140(1). Moreover, the prong 142(1)(2) is a distance W5 from the edge of the power tab 140(1) away from the edge 120. Knowledge of the width W1 and the distances W4 and W5 define the positions of the prongs 142(1)(1), 142(1)(2) on the power tab 140(1). In some implementations, the distances W4 and W5 are each between one and two times the width W2. For example, if W2 is between 0.5 mm and 2 mm, W4 and W5 are each between 0.5 mm and 4 mm.

As also shown in FIG. 1B, the prongs 142(1)(1), 142(1)(2) each have a length L2. The length L2 is defined by the trim/form process in which the prongs 142(1)(1), 142(1)(2) are cut from a frame portion of a leadframe (e.g., leadframe 105). In some implementations, the length L2 of the prongs 142(1)(1), 142(1)(2) is between two and four times the width W2 of the prongs 142(1)(1), 142(1)(2). For example, if W2 is between 0.5 mm and 2 mm, then L2 is between 1 mm and 8 mm.

The prongs 142(1)(1), 142(1)(2) each have an overhang over the surface of the molding compound 110 that is of length L3. The overhang is a consequence of the cutting of the prongs 142(1)(1), 142(1)(2) during the trim/form process in that the cutting needs to be performed slightly away from the edge of the molding compound 110. In some implementations, the length L3 is between one fourth and one half of the length L2 of the prongs 142(1)(1), 142(1)(2). For example, if the length L2 is between 1 mm and 8 mm, then L3 is between 0.25 mm and 4 mm. It is noted that the position of the power tab 140(1) with respect to the edge 122 is equal to L2−L3.

FIG. 2A is a diagram illustrating an example leadframe assembly 200. The leadframe assembly 200 includes a leadframe 210 and a semiconductor chip assembly 250.

The semiconductor chip assembly 250 is configured to provide power logic for the power module package 100 (FIG. 1A). As shown in FIG. 2A, the semiconductor chip assembly 250 includes a substrate 252 that includes a patterned metal layer 254, at least one semiconductor chip 256, and wirebonds 258. In some implementations, one or more of the wirebonds 258 can be replaced by one or more clips (not shown). In some implementations, the substrate 252 is a direct bonded metal (DBM) substrate. In some implementations, the substrate 252 is a direct bonded copper (DBC) substrate. In some implementations, the substrate 252 is exposed outside of a surface of a molded compound that is partially disposed over the leadframe assembly 200.

The leadframe 210 provides interconnects between the semiconductor chip assembly 250 and external connectors included in the leadframe 210. As shown in FIG. 2A, the leadframe 210 has not undergone the trim/form process. Accordingly, the leadframe 210 includes a frame portion 220 which is separated from the rest of the leadframe 210 during the trim/form process, signal terminals 230, and power tabs 240(1) and 240(2).

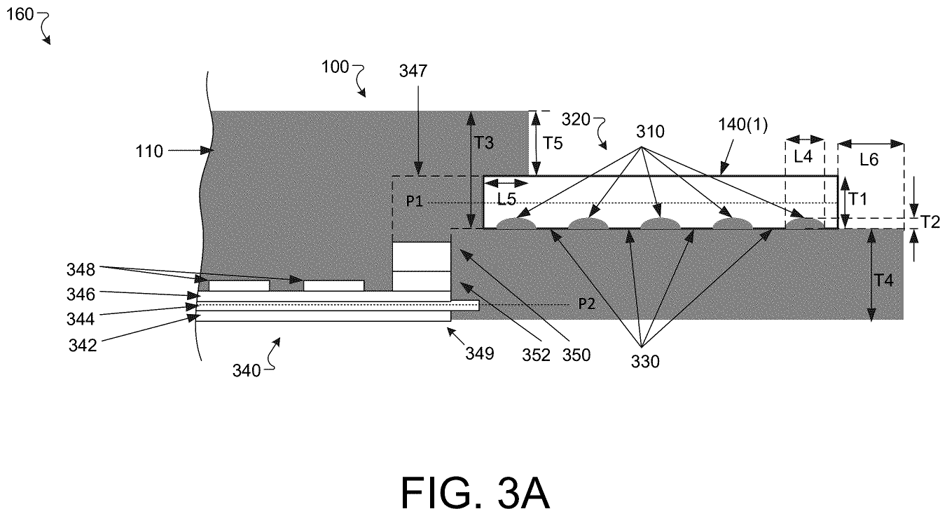

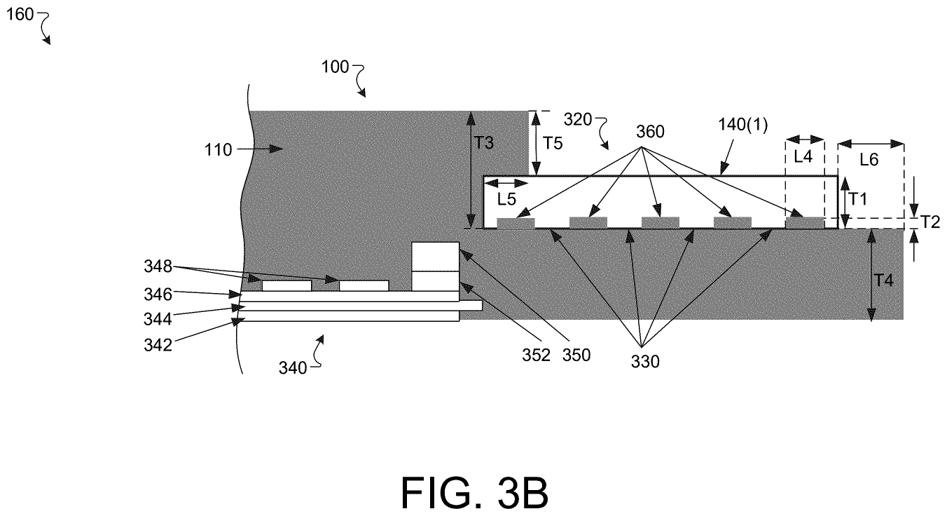

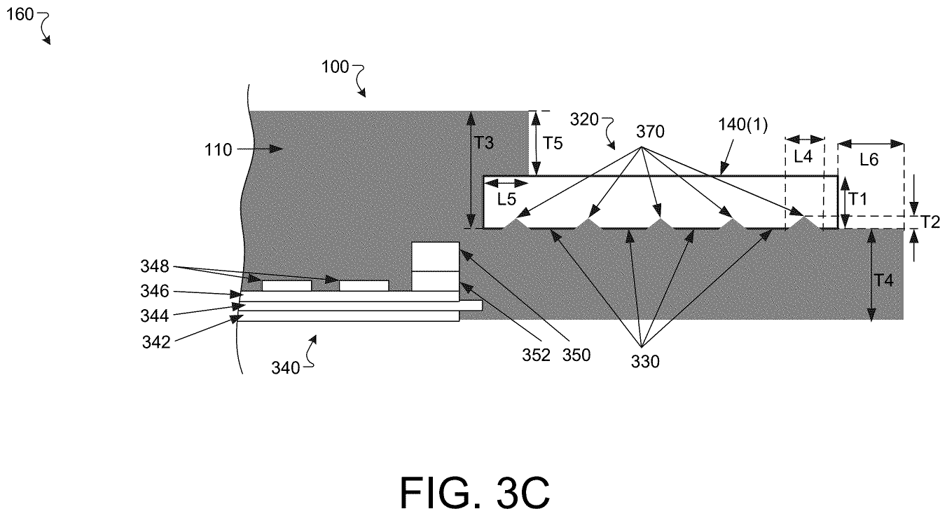

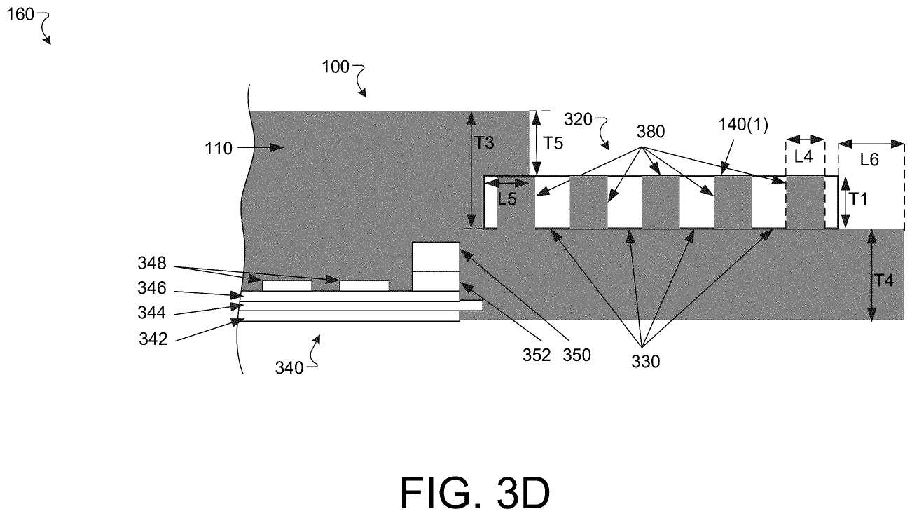

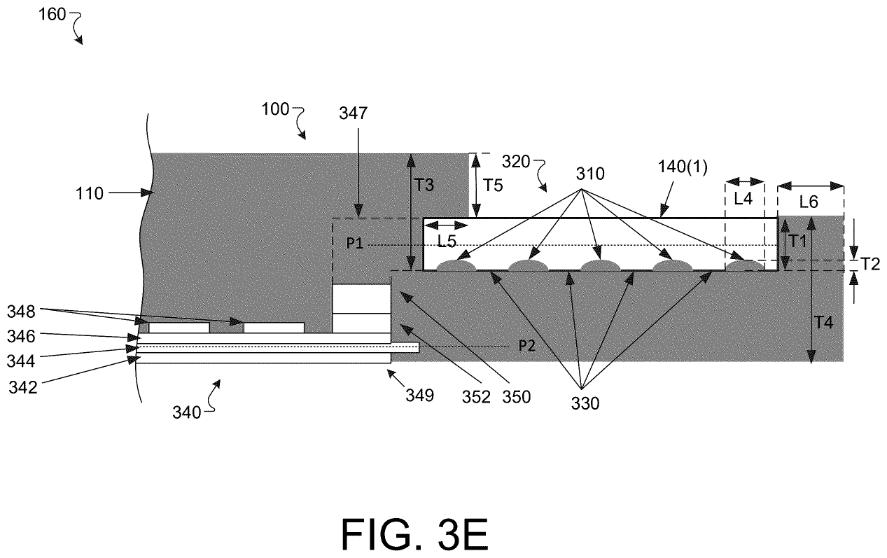

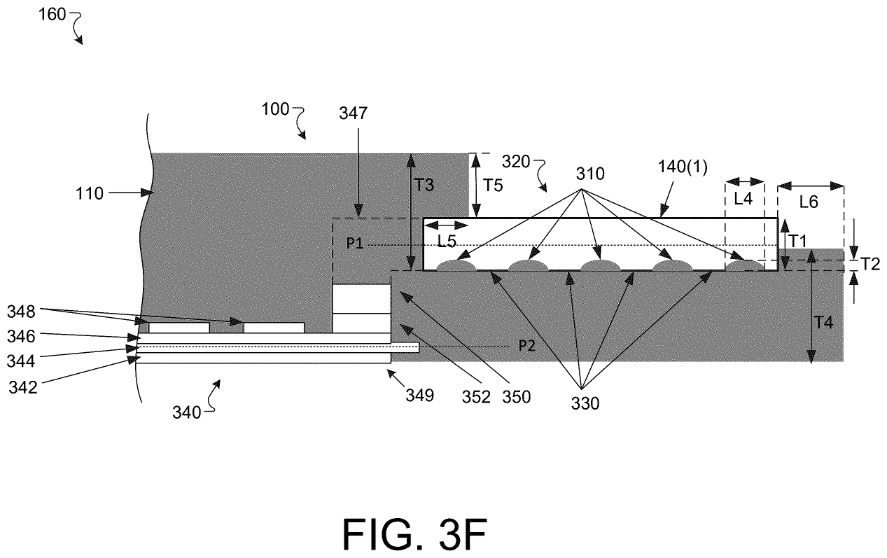

The signal terminals 230 and the power tabs 240(1) and 240(2) are connected to the semiconductor chip assembly 250 via conductive connectors, e.g., conductive connector 270. It is noted that the semiconductor chip assembly 250 is situated below (e.g., at a lower height in the direction of a thickness of the leadframe 210) the signal terminals 230 and power tabs 240(1) and 240(2) of the leadframe 210. A sloped portion 272 of the conductive connector 270 accounts for the height differential between the conductive connector 270 and the power tab 240(1). The power tab 240(1) is at a higher height within the leadframe 210 (along the Z direction out of the page) than the conductive connector 270 (along the Z direction into the page). More details about the different heights can be seen in, for example, FIGS. 3A through 3D.

In this implementation, current (e.g., power) flows between the semiconductor chip assembly 250 and the power tab 240(1) along a path 278 as shown in FIG. 2A (which includes the conductive connector 270). In this implementation there is a gap between the conductive connector 270 (and the sloped portion 272 of the conductive connector 270) and the power tab 240(1).

The connection may be effected using an attachment process. In some implementations, the attachment process involves applying a layer of solder (or sintering) between the conductive connector 270 and the patterned metal layer 254 of the semiconductor chip assembly 250. In some implementations, the attachment process involves a sintering between the conductive connector 270 and the patterned metal layer 254 of the semiconductor chip assembly 250.

The signal terminals 230 show similar connective topography as that of the power tab 140(1). As shown in FIG. 2A, a signal terminal 230 has a signal tab 282 and a conductive connector 276 having a sloped portion 272. The conductive connector 276 is coupled (e.g., electrically coupled) to the patterned metal layer 254 of the semiconductor chip assembly 250 via a solder or sintered connection.

As shown in FIG. 2A, the signal terminals 230 and the power tabs 240(1) and 240(2) are attached to one part of the frame portion 220, e.g., the horizontal part of the frame portion 220 as shown in FIG. 2A, via tie bars, e.g., tie bar 260.

In contrast, however, the power tabs 240(1) and 240(2) are attached to another part of the frame portion 220, e.g., the vertical part of the frame portion 220 as shown in FIG. 2A, via prongs 240(1)(1), 240(1)(2) corresponding to power tab 240(1), and prongs 240(2)(1) and 240(2)(2) corresponding to power tab 240(2). The advantage that the prongs, e.g., prongs 240(1)(1) and 240(1)(2) have over conventional tie bars is that because of the narrow width of the prongs 240(1)(1) and 240(1)(2), the cutting of the prongs 240(1)(1) and 240(1)(2) at cut line 262 during the trim/form process produces less mechanical stress in the power tab 240(1) than if the power tab 240(1) were connected to the frame portion 220 via a tie bar.

FIG. 2B is a diagram illustrating the power tab 240(1) of a leadframe (e.g., leadframe 210) during a trim/form process, after molding has occurred. As shown in FIG. 2B, the power tab 240(1) has a rectangular shape with a rounded corner near edge 222. In some implementations, the power tab 240(1) has a rectangular shape with rounded corners closer to the edge 222. In some implementations, the power tab 240(1) has a rectangular shape with a single rounded corner.

As shown in FIG. 2B, the power tab 240(1) has a width W1 of an edge parallel to edge 222 which, as discussed above, can be in some implementations between 5 mm and 10 mm. The power tab 240(1) has a length L1 of an edge parallel to edge 224 which can be in some implementations between 5 and 10 mm. The power tab 240(1) is located near the edge 224 at a distance W3 from the edge 224. In some implementations, the distance W3 is between 1 mm and 5 mm.

As shown in FIG. 2B and discussed with regard to FIG. 2A, the power tab 240(1) has prongs 242(1)(1) and 242(1)(2). As shown in FIG. 2B, the prongs 242(1)(1) and 242(1)(2) have the same width W2; in some implementations, the prongs 242(1)(1) and 242(1)(2) have different widths. In some implementations, the width W2 of each of the prongs 242(1)(1), 242(1)(2) is less than one half of the width of W1 of the power tab 240(1). In some implementations, the width W2 of each of the prongs 242(1)(1), 242(1)(2) is between one tenth and one fifth of the width W1 of the power tab 240(1). For example, if the width W1 of the power tab 240(1) is between 5 mm and 10 mm, the width W2 of each of the prongs 242(1)(1), 242(1)(2) is between 0.5 mm and 2 mm.

The prongs 242(1)(1), 242(1)(2) are, as shown in FIG. 2B, placed not necessarily symmetrically on the edge of the power tab closest to the edge 222. For example, as shown in FIG. 2B, the prongs 242(1)(1), 242(1)(2) are spaced a distance W4 apart on the power tab 240(1). Moreover, the prong 242(1)(2) is a distance W5 from the edge of the power tab 240(1) away from the edge 224. Knowledge of the width W1 and the distances W4 and W5 define the positions of the prongs 242(1)(1), 242(1)(2) on the power tab 240(1). In some implementations, the distances W4 and W5 are each between one and two times the width W2. For example, if W2 is between 0.5 mm and 2 mm, W4 and W5 are each between 0.5 mm and 4 mm.

As shown in FIG. 2B, the prongs 242(1)(1), 242(1)(2) are the attachment between the power tab 240(1) and a frame portion 220 of the leadframe. During the trim/form process, there is a cutting process for the prongs 242(1)(1), 242(1)(2) involving a lead cutter 280 that cuts the prongs 242(1)(1), 242(1)(2) at a specified location, e.g., at the cut line 262 (FIG. 2A). It is during this cut from lead cutter 280 that mechanical stress is transferred to the power tab 240(1). But because the prongs 242(1)(1), 242(1)(2) are narrower than a tie bar such as tie bar 260 (FIG. 2A), such mechanical stress is reduced and the chances of cracking due to stress are reduced.

As also shown in FIG. 2B, the prongs 142(1)(1), 142(1)(2) each have a length L2 which is defined by the distance between the edge of the power tab 240(1) closest to the edge 222 and the lead cutter 280. In some implementations, the length L2 of the prongs 242(1)(1), 242(1)(2) is between two and four times the width W2 of the prongs 242(1)(1), 242(1)(2). For example, if W2 is between 0.5 mm and 2 mm, then L2 is between 1 mm and 8 mm.

The prongs 242(1)(1), 242(1)(2) each have an overhang over the surface of the molding compound 110 that is of length L3. The overhang is a consequence of the cutting of the prongs 242(1)(1), 242(1)(2) during the trim/form process in that the cutting needs to be performed slightly away from the edge of the molding compound 110. In some implementations, the length L3 is between one fourth and one half of the length L2 of the prongs 242(1)(1), 242(1)(2). For example, if the length L2 is between 1 mm and 8 mm, then L3 is between 0.25 mm and 4 mm. It is noted that the position of the power tab 240(1) with respect to the edge 122 is equal to L2−L3.

FIG. 2C is a diagram illustrating an example power tab 240(1) after a trim/form process. As shown in FIG. 2C, the power tab 240(1) has a rectangular shape. In some implementations, the power tab 240(1) has a rectangular shape with rounded corners at any or all of the corners.

As shown in FIG. 2C, the power tab 240(1) has a width W1 of an edge parallel to edge 222 which, as discussed above, can be in some implementations between 5 mm and 10 mm. The power tab 240(1) has a length L1 of an edge parallel to edge 224 which can be in some implementations between 5 and 10 mm. The power tab 240(1) is located near the edge 224 at a distance W3 from the edge 224. In some implementations, the distance W3 is between 1 mm and 5 mm.

As shown in FIG. 2C and discussed with regard to FIG. 2A, the power tab 240(1) has prongs 242(1)(1) and 242(1)(2). As shown in FIG. 2C, the prongs 242(1)(1) and 242(1)(2) have the same width W2; in some implementations, the prongs 242(1)(1) and 242(1)(2) have different widths. In some implementations, the width W2 of each of the prongs 242(1)(1), 242(1)(2) is less than one half of the width of W1 of the power tab 240(1). In some implementations, the width W2 of each of the prongs 242(1)(1), 242(1)(2) is between one tenth and one fifth of the width W1 of the power tab 240(1). For example, if the width W1 of the power tab 240(1) is between 5 mm and 10 mm, the width W2 of each of the prongs 242(1)(1), 242(1)(2) is between 0.5 mm and 2 mm.

The prongs 242(1)(1), 242(1)(2) are, as shown in FIG. 2C, placed at the corners of the edge of power tab 240(1) closes to edge 222. Accordingly, the distance between the prongs 242(1)(1), 242(1)(2) is W4=W1−2*W2. The distance W5 defined in FIG. 2B is zero in this case.

As also shown in FIG. 2C, the prongs 142(1)(1), 142(1)(2) each have a length L2. In some implementations, the length L2 of the prongs 242(1)(1), 242(1)(2) is between two and four times the width W2 of the prongs 242(1)(1), 242(1)(2). For example, if W2 is between 0.5 mm and 2 mm, then L2 is between 1 mm and 8 mm.

The prongs 242(1)(1), 242(1)(2) each have an overhang over the surface of the molding compound 110 that is of length L3. In some implementations, the length L3 is between one fourth and one half of the length L2 of the prongs 242(1)(1), 242(1)(2). For example, if the length L2 is between 1 mm and 8 mm, then L3 is between 0.25 mm and 4 mm. It is noted that the position of the power tab 240(1) with respect to the edge 122 is equal to L2−L3.

FIG. 2D is a diagram illustrating an example power tab 240(1) after a trim/form process. As shown in FIG. 2D, the power tab 240(1) has a rectangular shape. In some implementations, the power tab 240(1) has a rectangular shape with rounded corners at any or all of the corners.

As shown in FIG. 2D, the power tab 240(1) has a width W1 of an edge parallel to edge 222 which, as discussed above, can be in some implementations between 5 mm and 10 mm. The power tab 240(1) has a length L1 of an edge parallel to edge 224 which can be in some implementations between 5 and 10 mm. The power tab 240(1) is located near the edge 224 at a distance W3 from the edge 224. In some implementations, the distance W3 is between 1 mm and 5 mm.

As shown in FIG. 2D, the power tab 240(1) has a single prong 290 of width W2. In some implementations, the width W2 of the prong 290 is less than one half of the width of W1 of the power tab 240(1). In some implementations, the width W2 of the prong 290 is between one tenth and one fifth of the width W1 of the power tab 240(1). For example, if the width W1 of the power tab 240(1) is between 5 mm and 10 mm, the width W2 of the prong 290 is between 0.5 mm and 2 mm.

The prong 290 as shown in FIG. 2D is located at the center of the edge of the power tab 240(1) closest to edge 222. In some implementations, a single prong is located off-center along the edge of the power tab 240(1) closest to edge 222.

As also shown in FIG. 2D, the prong 290 has a length L2. In some implementations, the length L2 of the prong 290 is between two and four times the width W2 of the prong 290. For example, if W2 is between 0.5 mm and 2 mm, then L2 is between 1 mm and 8 mm.

The prong 290 has an overhang over the surface of the molding compound 110 that is of length L3. In some implementations, the length L3 is between one fourth and one half of the length L2 of the prong 290. For example, if the length L2 is between 1 mm and 8 mm, then L3 is between 0.25 mm and 4 mm. It is noted that the position of the power tab 240(1) with respect to the edge 122 is equal to L2−L3.

FIG. 3A is a diagram illustrating a cross-sectional view of the power module package 100. The cross-sectional view is taken along cross-section 160 (FIG. 1A). As shown in FIG. 3A, the power module package 100 includes a molding compound 110, a signal terminal 130, a power tab 140(1), and a semiconductor chip assembly 340.

The power tab 140(1) is located in a recess 320 of the molding compound 110. The depth of the recess is shown at thickness T5. The recess 320 has a depth T3 that is the same depth as that for a signal terminal (not shown). In some implementations, the thickness T4 of the molding compound 110 on which the power tab 140(1) is disposed is between one quarter and one half of the thickness T3+T4 of the molding compound 110 disposed over the semiconductor chip assembly 150 and the leadframe 105.

In some implementations, the thickness T4 can be greater than shown in FIGS. 3A through 3D. In some implementations, the thickness T4 can be the same as the thickness T 1+T4 so that a top surface of the power tab 140(1) is the same as a top surface of the molding compound 110. Such implementations are shown in at least FIGS. 3E and 3F. The implementations of FIGS. 3E and 3F can be combined with any combination of the textured surfaces shown in FIGS. 3A through 3D.

It is noted that, as shown in FIG. 3A, the power tab 140(1) is encapsulated in the molding compound 110 over a length L5. Moreover, the power tab 140(1) is positioned away from the edge of the surface of the molding compound 110 by a distance L6. The distance L6 is equal to the difference between the distances L2 and L3 as shown in FIG. 2B.

As shown in FIG. 3A, the power tab 140(1) a textured profile in the form of grooves 310 and flat portions 330. The flat portions 330 are portions of the bottom surface of the power tab 140(1) in which the thickness T1 of the power tab 140(1) is the nominal thickness. The grooves 310, on the other hand, are portions of the bottom surface of the power tab 140(1) in which the thickness of the power tab 140(1) varies with position along the bottom surface. The grooves 310 are characterized by their shape and maximum depth T2 into the power tab 140(1). The molding compound 110 fills the spaces provided by the grooves 310.

As shown in FIG. 3A, the grooves 310 take the form of round arcs. In some implementations, the round arcs are circular arcs. In some implementations, the round arcs are elliptical arcs. In some implementations, the round arcs are oval arcs. In some implementations shown in FIGS. 3B and 3C, the grooves 310 are not round, for example having polygonal shapes. For example, grooves 310 can be triangles. In some implementations, the grooves 310 can be rectangular. In some implementations, the grooves 310 can be square.

As also shown in FIG. 3A, the grooves 310 have a maximum depth T2 that is about one fourth of the thickness T1 of the power tab 140(1). In some implementations, the grooves 310 have a maximum depth T2 between one fourth and one half of the thickness T1 of the power tab 140(1). In implementations in which the power tab 140(1) having a thickness T1 between 0.5 mm and 1.0 mm, the maximum depth T2 of the grooves 310 may be between 0.125 mm and 0.5 mm.

The length L4 of the grooves 310 as shown in FIG. 3A can be deduced from knowledge of the length L1 (see FIG. 2B) of the power tab 140(1) and the number of grooves 310. For example, if the length L1 of the power tab 140(1) is 5 mm, then the length L4 of each groove 310 can be seen to be about one tenth of the length L1 of the power tab 140(1), or about 0.5 mm. The textured profile of the bottom surface of the power tab 140(1) can be seen in this example to be periodic with a duty cycle of about unity. Such a periodic textured profile with 0.5 mm grooves 310 and 0.5 mm flat portions 330 can be patterned on the bottom surface of the power tab 140(1) using, in some implementations, a direct etch process is used to create the textured profile including of grooves 310 and flat portions 330. In some implementations, the textured profile is irregular.

As shown in FIG. 3A, the semiconductor chip assembly 340 includes a first metal layer 342, an insulating layer 344, a patterned metal layer 346, and semiconductor die 348. Together, the first metal layer 342, insulating layer 344, and patterned metal layer 346 are included in a substrate 349, e.g., a direct bonded metal (DBM) substrate. The substrate 349 can be a part of the semiconductor chip assembly 340. The power tab 140(1) is connected to the semiconductor chip assembly 340 via a conductive connector 350. The conductive connector 350 is attached to the patterned metal layer 346 via a layer of solder 352; in some implementations, however, the conductive connector 350 may be attached to the patterned metal layer 346 via a sintering process.

As shown in FIG. 3A, the power tab 140(1) and the semiconductor chip assembly 340 are disposed within the power module package 100 in different planes P1 and P2, respectively. As shown, the power tab 140(1) is aligned along plane P1, which is parallel to plane P2 along which the semiconductor chip assembly 340 (and the substrate 349) is aligned. FIG. 3A also illustrates a connection 347 (illustrated with a dashed line because the actual element is further into the page within the power module package 100) between the power tab 140(1) and the conductive connector 350, which corresponds with the sloped portion 272 of the conductive connector 270 shown in FIG. 2A. The elements described in connection with FIG. 3A (e.g., connection 347, plane P1 and plane P2), while not shown in FIGS. 3B, 3C, and 3D, are also applicable to these figures.

In some implementations and as shown in FIG. 3A, the first metal layer 342 is exposed outside of the molding compound 110. This may be advantageous because the first metal layer 342 can act as a heat sink for the insulating layer 344. In some implementations, however, the semiconductor chip assembly 340 is fully encapsulated by the molding compound 110.

FIG. 3B is a diagram illustrating a cross-sectional view of the power module package 100. The cross-sectional view is taken along cross-section 160 (FIG. 1A). As shown in FIG. 3A, the power module package 100 includes a molding compound 110, a signal terminal 130, a power tab 140(1), and a semiconductor chip assembly 340.

The power tab 140(1) is located in a recess 320 of the molding compound 110. The recess 320 has a depth T3 that is the same depth as that for a signal terminal (not shown). In some implementations, the thickness T4 of the molding compound 110 on which the power tab 140(1) is disposed is between one quarter and one half of the thickness T3+T4 of the molding compound 110 disposed over the semiconductor chip assembly 150 and the leadframe 105.

It is noted that, as shown in FIG. 3B, the power tab 140(1) is encapsulated in the molding compound 110 over a length L5. In some implementations, the distance L5 is zero such that the power tab 140(1) is not covered by the molding compound 110 over the length L5. Moreover, the power tab 140(1) is positioned away from the edge of the surface of the molding compound 110 by a distance L6. The distance L6 is equal to the difference between the distances L2 and L3 as shown in FIG. 2B.

As shown in FIG. 3B, the power tab 140(1) a textured profile in the form of grooves 310 and flat portions 330. The flat portions 330 are portions of the bottom surface of the power tab 140(1) in which the thickness T1 of the power tab 140(1) is the nominal thickness. The grooves 310, on the other hand, are portions of the bottom surface of the power tab 140(1) in which the thickness of the power tab 140(1) varies with position along the bottom surface. The grooves 310 are characterized by their shape and depth T2 into the power tab 140(1). The molding compound 110 fills the spaces provided by the grooves 310.

As shown in FIG. 3B, the grooves 310 take the form of rectangles. In some implementations, the rectangles are squares.

As also shown in FIG. 3B, the grooves 310 have a depth T2 that is about one fourth of the thickness T1 of the power tab 140(1). In some implementations, the grooves 310 have a depth T2 between one fourth and one half of the thickness T1 of the power tab 140(1). In implementations in which the power tab 140(1) having a thickness T1 between 0.5 mm and 1.0 mm, the depth T2 of the grooves 310 may be between 0.125 mm and 0.5 mm.

The length L4 of the grooves 310 as shown in FIG. 3B can be deduced from knowledge of the length L1 (see FIG. 2B) of the power tab 140(1) and the number of grooves 310. For example, if the length L1 of the power tab 140(1) is 5 mm, then the length L4 of each groove 310 can be seen to be about one tenth of the length L1 of the power tab 140(1), or about 0.5 mm. The textured profile of the bottom surface of the power tab 140(1) can be seen in this example to be periodic with a duty cycle of about unity. Such a periodic textured profile with 0.5 mm grooves 310 and 0.5 mm flat portions 330 can be patterned on the bottom surface of the power tab 140(1) using, in some implementations, a direct etch process is used to create the textured profile including of grooves 310 and flat portions 330.

As shown in FIG. 3B, the semiconductor chip assembly 340 includes a first metal layer 342, an insulating layer 344, a patterned metal layer 346, and semiconductor die 348. The power tab 140(1) is connected to the semiconductor chip assembly 340 via a conductive connector 350. The conductive connector 350 is attached to the patterned metal layer 346 via a layer of solder 352; in some implementations, however, the conductive connector 350 may be attached to the patterned metal layer 346 via a sintering process.

In some implementations and as shown in FIG. 3B, the first metal layer 342 is exposed outside of the molding compound 110. This may be advantageous because the first metal layer 342 can act as a heat sink for the insulating layer 344. In some implementations, however, the semiconductor chip assembly 340 is fully encapsulated by the molding compound 110.

FIG. 3C is a diagram illustrating a cross-sectional view of the power module package 100. The cross-sectional view is taken along cross-section 160 (FIG. 1A). As shown in FIG. 3A, the power module package 100 includes a molding compound 110, a signal terminal 130, a power tab 140(1), and a semiconductor chip assembly 340.

The power tab 140(1) is located in a recess 320 of the molding compound 110. The recess 320 has a depth T3 that is the same depth as that for a signal terminal (not shown). In some implementations, the thickness T4 of the molding compound 110 on which the power tab 140(1) is disposed is between one quarter and one half of the thickness T3+T4 of the molding compound 110 disposed over the semiconductor chip assembly 150 and the leadframe 105.

It is noted that, as shown in FIG. 3C, the power tab 140(1) is encapsulated in the molding compound 110 over a length L5. Moreover, the power tab 140(1) is positioned away from the edge of the surface of the molding compound 110 by a distance L6. The distance L6 is equal to the difference between the distances L2 and L3 as shown in FIG. 2B.

As shown in FIG. 3C, the power tab 140(1) a textured profile in the form of grooves 310 and flat portions 330. The flat portions 330 are portions of the bottom surface of the power tab 140(1) in which the thickness T1 of the power tab 140(1) is the nominal thickness. The grooves 310, on the other hand, are portions of the bottom surface of the power tab 140(1) in which the thickness of the power tab 140(1) varies with position along the bottom surface. The grooves 310 are characterized by their shape and maximum depth T2 into the power tab 140(1). The molding compound 110 fills the spaces provided by the grooves 310.

As shown in FIG. 3C, the grooves 310 take the form of triangles. As also shown in FIG. 3B, the grooves 310 have a maximum depth T2 that is about one fourth of the thickness T1 of the power tab 140(1). In some implementations, the grooves 310 have a maximum depth T2 between one fourth and one half of the thickness T1 of the power tab 140(1). In implementations in which the power tab 140(1) having a thickness T1 between 0.5 mm and 1.0 mm, the maximum depth T2 of the grooves 310 may be between 0.125 mm and 0.5 mm.

The length L4 of the grooves 310 as shown in FIG. 3B can be deduced from knowledge of the length L1 (see FIG. 2B) of the power tab 140(1) and the number of grooves 310. For example, if the length L1 of the power tab 140(1) is 5 mm, then the length L4 of each groove 310 can be seen to be about one tenth of the length L1 of the power tab 140(1), or about 0.5 mm. The textured profile of the bottom surface of the power tab 140(1) can be seen in this example to be periodic with a duty cycle of about unity. Such a periodic textured profile with 0.5 mm grooves 310 and 0.5 mm flat portions 330 can be patterned on the bottom surface of the power tab 140(1) using, in some implementations, a direct etch process is used to create the textured profile including of grooves 310 and flat portions 330.

As shown in FIG. 3C, the semiconductor chip assembly 340 includes a first metal layer 342, an insulating layer 344, a patterned metal layer 346, and semiconductor die 348. The power tab 140(1) is connected to the semiconductor chip assembly 340 via a conductive connector 350. The conductive connector 350 is attached to the patterned metal layer 346 via a layer of solder 352; in some implementations, however, the conductive connector 350 may be attached to the patterned metal layer 346 via a sintering process.

In some implementations and as shown in FIG. 3C, the first metal layer 342 is exposed outside of the molding compound 110. This may be advantageous because the first metal layer 342 can act as a heat sink for the insulating layer 344. In some implementations, however, the semiconductor chip assembly 340 is fully encapsulated by the molding compound 110.

FIG. 3D is a diagram illustrating a cross-sectional view of the power module package 100. The cross-sectional view is taken along cross-section 160 (FIG. 1A). As shown in FIG. 3A, the power module package 100 includes a molding compound 110, a power tab 140(1), and a semiconductor chip assembly 340.

The power tab 140(1) is located in a recess 320 of the molding compound 110. The recess 320 has a depth T3 that is the same depth as that for a signal terminal (not shown). In some implementations, the thickness T4 of the molding compound 110 on which the power tab 140(1) is disposed is between one quarter and one half of the thickness T3+T4 of the molding compound 110 disposed over the semiconductor chip assembly 150 and the leadframe 105.

As shown in FIG. 3D, the power tab 140(1) a textured profile in the form of holes 380 and flat portions 330. The flat portions 330 are portions of the bottom surface of the power tab 140(1) in which the thickness of the power tab 140(1) is the nominal thickness T1. The holes 380, on the other hand, extend through the thickness T1 of the power tab 140(1). The molding compound 110 fills the spaces provided by the holes 380.

The width L4 of the holes 380 as shown in FIG. 3D can be deduced from knowledge of the length L1 of the power tab 140(1). For example, if the length L1 of the power tab 140(1) is 5 mm, then the width L4 of each hole 380 can be seen to be about one tenth of the length L1 of the power tab 140(1), or about 0.5 mm. The textured profile of the bottom surface of the power tab 140(1) can be seen in this example to be periodic with a duty cycle of about unity. Such a periodic textured profile with 0.5 mm holes 380 and 0.5 mm flat portions 330 can be patterned on the bottom surface of the power tab 140(1) using, in some implementations, a direct etch process is used to create the textured profile including of holes 380 and flat portions 330.

As shown in FIG. 3D, the semiconductor chip assembly 340 includes a first metal layer 342, an insulating layer 344, a patterned metal layer 346, and semiconductor die 348. The power tab 140(1) is connected to the semiconductor chip assembly 340 via a conductive connector 350. The conductive connector 350 is attached to the patterned metal layer 346 via a layer of solder 352; in some implementations, however, the conductive connector 350 may be attached to the patterned metal layer 346 via a sintering process.

In some implementations and as shown in FIG. 3D, the first metal layer 342 is exposed outside of the molding compound 110. This may be advantageous because the first metal layer 342 can act as a heat sink for the insulating layer 344. In some implementations, however, the semiconductor chip assembly 340 is fully encapsulated by the molding compound 110.

In some implementations, the textured profiles described herein can have any combination of the textures profiles shown in FIGS. 3A through 3D. For example, a portion of the textured profile of FIG. 3A can be combined with a portion of the texture profile of FIG. 3B.

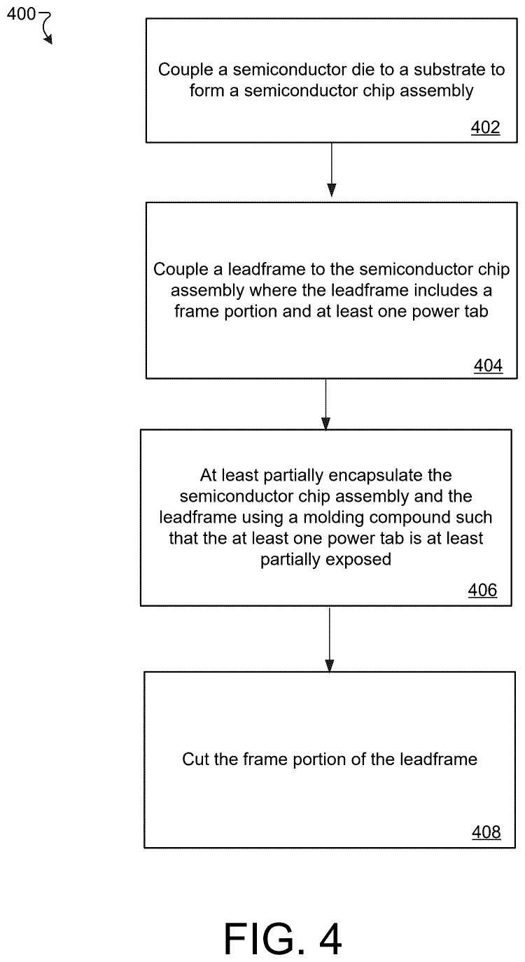

FIG. 4 is a flow chart illustrating an example method 400 of assembling a power module package, e.g., power module package 100 (FIG. 1A).

At 402, a semiconductor die (e.g., semiconductor die 348 of FIG. 3A) is coupled to a substrate (e.g., metal layer 342, insulating layer 344, and patterned metal layer 346 of FIG. 3A) to form a semiconductor chip assembly (e.g., semiconductor chip assembly 150 of FIG. 1A). In some implementation, the semiconductor die can be coupled using a solder or a sintering process.

At 404, a leadframe is coupled to the semiconductor chip assembly where the leadframe includes a frame portion and at least one power tab. In other words, a leadframe (e.g., leadframe 210 of FIG. 2A) is connected to the semiconductor chip assembly. The leadframe includes a frame portion (e.g., frame portion 220 of FIG. 2A) and at least one power tab (e.g., power tab 240(1) of FIG. 2A) connected to the frame portion by at least one prong (e.g., prong 242(1)(1) of FIG. 2A), the at least one prong having a width (e.g., W2) less than one half of a width (e.g., W1) of the at least one power tab.

At 406, a molding compound (e.g., molding compound 110 of FIG. 1A) is partially disposed over the semiconductor chip assembly and the leadframe such that the at least one power tab is at least partially exposed. In other words, the semiconductor chip assembly and the leadframe are at least partially encapsulated using a molding compound.

At 408, the frame portion of the leadframe is cut (e.g., trimmed). In other words, the trim/form process described in connection with FIG. 2B is performed.

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

The various apparatus and techniques described herein may be implemented using various semiconductor processing and/or packaging techniques. Some embodiments may be implemented using various types of semiconductor processing techniques associated with semiconductor substrates including, but not limited to, for example, Silicon (Si), Gallium Arsenide (GaAs), Silicon Carbide (SiC), and/or so forth.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

In some implementations, the direct bonded metal (DBM) substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al2O3) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, one or more portions of a leadframe can be coupled to a pad (e.g., a bond pad) on at least a portion of a DBM substrate.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

In some implementations, a module (e.g., a package including a semiconductor device) can be included in another module. The module can be referred to as a package. For example, one or more modules can be one or more sub modules included within another module. In other words, a first module can be included as a sub module within a second module.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

In some aspects, the techniques described herein relate to a power module package, including: a semiconductor chip assembly; a leadframe connected to the semiconductor chip assembly, the leadframe including at least one power tab through which current associated with the semiconductor chip assembly flows; and a molding compound partially disposed over the semiconductor chip assembly and the leadframe, the at least one power tab being exposed outside of a surface of the molding compound.

In some aspects, the techniques described herein relate to a power module package, wherein the at least one power tab includes at least one prong extending beyond the surface of the molding compound.

In some aspects, the techniques described herein relate to a power module package, wherein the at least one prong includes a prong extending beyond the surface of the molding compound from a corner of the at least one power tab.

In some aspects, the techniques described herein relate to a power module package, wherein the at least one prong has a width that is less than one half of a width of the at least one power tab.

In some aspects, the techniques described herein relate to a power module package, wherein the at least one power tab includes a power tab disposed in a corner of the surface of the molding compound.

In some aspects, the techniques described herein relate to a power module package, wherein a thickness of the molding compound on which the at least one power tab is disposed is less than a thickness of the molding compound disposed over the semiconductor chip assembly and the leadframe.

In some aspects, the techniques described herein relate to a power module package, wherein the thickness of the molding compound on which the at least one power tab is disposed is between one quarter and one half of the thickness of the molding compound disposed over the semiconductor chip assembly and the leadframe.

In some aspects, the techniques described herein relate to a power module package, wherein a bottom surface of the at least one power tab has a textured profile.

In some aspects, the techniques described herein relate to a power module package, wherein the textured profile is periodic.

In some aspects, the techniques described herein relate to a power module package, wherein the textured profile includes a groove and a flat portion, the groove extending through at least a portion of a thickness of the at least one power tab.

In some aspects, the techniques described herein relate to a power module package, wherein the groove has a round shape.

In some aspects, the techniques described herein relate to a power module package, wherein the groove extends through the thickness of the at least one power tab.

In some aspects, the techniques described herein relate to a power module package, wherein the groove extends through between one-quarter and one-half of the thickness of the at least one power tab.

In some aspects, the techniques described herein relate to a power module package, wherein a thickness of the at least one power tab is between 0.5 mm and 1 mm.

In some aspects, the techniques described herein relate to a power module package, wherein a width of the at least one power tab is between 5 mm and 10 mm.

In some aspects, the techniques described herein relate to a leadframe, including: a frame portion; and at least one power tab connected to the frame portion by at least one prong, the at least one prong having a width less than one half of a width of the at least one power tab.

In some aspects, the techniques described herein relate to a leadframe, wherein a bottom surface of the at least one power tab has a textured profile.

In some aspects, the techniques described herein relate to a leadframe, wherein the textured profile is periodic.

In some aspects, the techniques described herein relate to a leadframe, wherein the textured profile includes a groove and a flat portion.

In some aspects, the techniques described herein relate to a leadframe, wherein the groove extends through a thickness of the at least one power tab.

In some aspects, the techniques described herein relate to a method, including: coupling a semiconductor die to a substrate to form a semiconductor chip assembly; coupling a leadframe to the semiconductor chip assembly, the leadframe including a frame portion and at least one power tab; at least partially encapsulating the semiconductor chip assembly and the leadframe using a molding compound such that the at least one power tab is at least partially exposed; and cutting the frame portion of the leadframe.

In some aspects, the techniques described herein relate to a method, wherein a bottom surface of the at least one power tab has a textured profile.

In some aspects, the techniques described herein relate to a power module package, including: a semiconductor chip assembly; a leadframe connected to the semiconductor chip assembly, the leadframe including at least one power tab through which current associated with the semiconductor chip assembly flows; and a molding compound partially disposed over the semiconductor chip assembly and the leadframe, the at least one power tab being recessed within the molding compound.

In some aspects, the techniques described herein relate to a power module package, wherein the at least one power tab includes a power tab disposed in a corner of a surface of the molding compound.

In some aspects, the techniques described herein relate to a power module package, wherein a thickness of the molding compound on which the at least one power tab is disposed is less than a thickness of the molding compound disposed over the semiconductor chip assembly and the leadframe.

In some aspects, the techniques described herein relate to a power module package, wherein a bottom surface of the at least one power tab has a textured profile.

In some aspects, the techniques described herein relate to a power module package, wherein the textured profile is periodic.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

What is claimed is:

1. A power module package, comprising:
a semiconductor chip assembly;
a leadframe connected to the semiconductor chip assembly, the leadframe including at least one power tab through which current associated with the semiconductor chip assembly flows; and
a molding compound partially disposed over the semiconductor chip assembly and the leadframe, the at least one power tab being exposed outside of a surface of the molding compound.

2. The power module package of claim 1, wherein the at least one power tab includes at least one prong extending beyond the surface of the molding compound.

3. The power module package of claim 2, wherein the at least one prong includes a prong extending beyond the surface of the molding compound from a corner of the at least one power tab.

4. The power module package of claim 2, wherein the at least one prong has a width that is less than one half of a width of the at least one power tab.

5. The power module package of claim 1, wherein the at least one power tab includes a power tab disposed in a corner of the surface of the molding compound.

6. The power module package of claim 1, wherein a thickness of the molding compound on which the at least one power tab is disposed is less than a thickness of the molding compound disposed over the semiconductor chip assembly and the leadframe.

7. The power module package of claim 6, wherein the thickness of the molding compound on which the at least one power tab is disposed is between one quarter and one half of the thickness of the molding compound disposed over the semiconductor chip assembly and the leadframe.

8. The power module package of claim 1, wherein a bottom surface of the at least one power tab has a textured profile.

9. The power module package of claim 8, wherein the textured profile is periodic.

10. The power module package of claim 8, wherein the textured profile includes a groove and a flat portion, the groove extending through at least a portion of a thickness of the at least one power tab.

11. The power module package of claim 10, wherein the groove has a round shape.

12. The power module package of claim 10, wherein the groove extends through the thickness of the at least one power tab.

13. The power module package of claim 10, wherein the groove extends through between one-quarter and one-half of the thickness of the at least one power tab.

14. A power module package, comprising:
a semiconductor chip assembly;
a leadframe connected to the semiconductor chip assembly, the leadframe including at least one power tab through which current associated with the semiconductor chip assembly flows; and
a molding compound partially disposed over the semiconductor chip assembly and the leadframe, the at least one power tab being recessed within the molding compound.

15. The power module package of claim 14, wherein the at least one power tab includes a power tab disposed in a corner of a surface of the molding compound.

16. The power module package of claim 14, wherein a thickness of the molding compound on which the at least one power tab is disposed is less than a thickness of the molding compound disposed over the semiconductor chip assembly and the leadframe.

17. The power module package of claim 14, wherein a bottom surface of the at least one power tab has a textured profile.

18. The power module package of claim 17, wherein the textured profile is periodic.

19. A method, comprising:
coupling a semiconductor die to a substrate to form a semiconductor chip assembly;
coupling a leadframe to the semiconductor chip assembly, the leadframe including a frame portion and at least one power tab;
at least partially encapsulating the semiconductor chip assembly and the leadframe using a molding compound such that the at least one power tab is at least partially exposed; and
cutting the frame portion of the leadframe.

20. The method of claim 19, wherein a bottom surface of the at least one power tab has a textured profile.
